(19) United States
(12) Patent Application Publication
(10) Pub. No.: US 2026/0201607 A1
(43) Pub. Date: Jul. 16, 2026

(54) METHODS OF GROWING CO-DOPED CERIUM CALCIUM LUTETIUM-YTTRIUM OXYORTHOSILICATE SCINTILLATION CRYSTALS AND RELATED CRYSTALS

(71) Applicant: Pacific Innovations Pte Ltd, Singapore (SG)

(72) Inventors: Faouzi Zerrouk, Vancouver (CA); Thomas Loop, Seattle, WA (US); XiaoWei Huang, Shanghai (CN)

(73) Assignee: Pacific Innovations Pte Ltd, Singapore (SG)

(21) Appl. No.: 19/442,847

(22) Filed: Mar. 27, 2026

Related U.S. Application Data
(62) Division of application No. 18/814,879, filed on Aug. 26, 2024.
(60) Provisional application No. 63/610,346, filed on Dec. 14, 2023.

(51) Int. Cl. C30B 29/34; C30B 15/04; C30B 15/14; C30B 33/02

(52) U.S. Cl. CPC C30B 29/34; C30B 15/04; C30B 15/14; C30B 33/02

(57) ABSTRACT

The method involves growing a boule of co-doped LYSO:Ce,Ca scintillation crystal containing Ce³⁺ ions and Ce⁴⁺ ions in a ratio of about 1:1, wherein the grown boule is substantially free of Li⁺ ions and Mg²⁺ ions. This is achieved by providing a specialized crystal growing device having an inner iridium crucible and loading it with specific oxides and a carbonate salt in specific amounts. The loaded iridium crucible is then subjected to a vacuum and then pressurized with a specific gas mixture consisting mostly of Ar admixed with a small amount of CO. The loaded and pressurized iridium crucible is then heated to yield a melt, into which a seed crystal is placed to grow (by way of the Czochrolaski pull method) an unfinished crystalline boule. This unfinished boule is then annealed in the same special pressurized atmosphere to yield the final boule of co-doped LYSO:Ce, Ca scintillation crystal.

### TECHNICAL FIELD

The present invention relates to the field of crystal growth and, more particularly, to methods of growing advanced cerium-activated lutetium-based oxyorthosilicate scintillation crystals for use in molecular imaging and high energy physics.

### BACKGROUND OF THE INVENTION

Cerium-activated lutetium-yttrium oxyorthosilicate, commonly identified as LYSO:Ce (or simply as LYSO), is among the most technologically advanced group of scintillation crystals thus far created by mankind. Although initially developed for radiation detection and medical imaging (namely, Positron Emission Tomography (PET)) towards the end of the last millennium, LYSO:Ce scintillation crystals have more recently found expanded uses in, among other things, High Energy Physics (HEP) applications (especially in the context of high luminosity particle colliders). Indeed, during the past decade manmade LYSO:Ce scintillation crystals have been formulated and used by scientist to develop cutting-edge high precision electromagnetic calorimeters such as the one designed for the Mule experiment [Mu2e collaboration, Mu2e Conceptual Design Report, Tech. Rep. FERMILAB-TM-2545, FERMILAB-DESIGN-2012-03, FERMILAB (2012)] and the CCALT forward calorimeter of the KLOE-2 experiment [M. Cordelli et al., CCALT: A crystal calorimeter for the KLOE-2 experiment, Journal of Physics: Conference Series 293 (2011)].

Unlike other types of scintillation crystals, LYSO:Ce scintillation crystals advantageously possess a high mass density (roughly twice the density of NaI(TI)), fast scintillation kinetics (roughly six times faster decay time than BGO), and a high light yield (about 40000 ph/MeV). In the field of crystal growth, LYSO:Ce scintillation crystals are known for their excellent scintillation properties. The growth of such crystals, however, is not without its challenges. The process often requires precise control over the growth conditions, including temperature, pressure, and the composition of the growth medium and surrounding atmosphere. Furthermore, the choice of crucible design and its insulation materials can significantly impact the quality and properties of the grown crystal. Finally, the presence of different co-dopants, impurities, and defects are known to play important roles in scintillation crystal dynamics and, therefore, need to be tightly controlled.

In addition, the post-growth treatment of the grown crystal, such as annealing, can also affect the crystal's properties. The annealing process must also be carefully controlled to ensure that the crystal achieves the desired properties.

U.S. Pat. No. 4,958,080 to Melcher, a pioneering patent in the field, teaches a single crystal scintillator composed of cerium-activated lutetium oxyorthosilicate (commonly identified as LSO:Ce, or simply as LSO) having the formula Ce₂ₓLu₂₍₁₋ₓ₎SiO₅. The original LSO crystal were developed for uses in high-energy radiation detectors.

Lutetium oxyorthosilicate (LSO) crystals are known to have a lattice structure composed of lutetium (Lu), silicon (Si), and oxygen (O) in proportions given by the general formula Lu₂SiO₅; that is, a formula unit with two lutetium atoms, one silicon atom, and five oxygen atoms. It is a 1:1 mole ratio compound in the binary rare-earth silicate system composed of one Lu₂O₃ mole and one SiO₂ mole. Upon mixing, melting, and subsequent solidification of these two initial starting oxides, a new composition is formed:

$$1 mol [ {Lu}_{2} {O}_{3} ] + 1 mol [ {SiO}_{2} ] \to 1 mol [ {Lu}_{2} {SiO}_{5} ]$$

The LSO solid-state composition has a ratio of lutetium to silicon to oxygen of 2:1:5 (Lu₂SiO₅). That is, two lutetium to each one silicon and five oxygen atoms. In order to attain scintillation attributes, the starting oxide material are doped with small amounts of cerium oxide (CeO₂) to produce, after melting and subsequent growing, cerium-activated lutetium oxyorthosilicate crystal Ce:LSO, wherein reduced trivalent cerium Ce³⁺ ions substitute for trivalent lutetium Lu³⁺ ions within the overall crystal lattice structure. The substituted trivalent cerium Ce³⁺ ions act as sensitizers, improving the efficiency of energy transfer and light production of the crystal. The amount of cerium substituted for lutetium, which is assigned a value of x, is the same value that reduces the amount of lutetium, resulting in lutetium's new value, which may be expressed as (1-x). Because cerium replaces some of the lutetium, it may be said that cerium oxide belongs to the “lutetium group,” which, as a whole, still maintains the general 1:1 mole ratio:

(1-x)mol[Lu₂O₅]+(x)mol[CeOg]=1mol Lu group oxides:1 mol Si group oxides

Generally, this may be expressed with the following reaction leading to cerium-activated lutetium oxyorthosilicate (Ce:LSO):

$$( 1 - x ) mol {Lu}_{2} {O}_{3} + x mol {CeO}_{2} + 1 mol {SiO}_{2} \to 1 mol {Ce}_{2 x} {Lu}_{2 ( 1 - x )} {SiO}_{5}$$

In this composition, x is defined as 0.001<x<0.0045. Therefore, the entire range of each element's formula unit (f.u.) value claimed within the general composition of the '080 patent to Melcher may be expressed as the following:

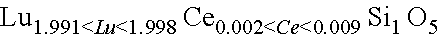

U.S. Pat. No. 6,278,832 to Zagumennyi et al., another pioneering patent in the field, teaches enhanced scintillation crystals composed of cerium-activated lutetium oxyorthosilicate having the formula Lu_{1-y}Me_{y}A₁₋ₓCeₓSiO₅ wherein at least two additional variable elements, “Me” and “A” are added (inclusive of divalent and trivalent metals). In some embodiments, the substituted co-doped Ce:LSO and/or Ce:LYSO scintillation crystals include oxygen vacancies ( [symbol] ) resulting from charge imbalances. The oxygen vacancies are recited to reflect an accurate value of oxygen in the final solid-state crystal composition. When the crystal forms, it must obey the conservation of charge neutrality laws, or, in other words, the total positive ions must equal the total negative ions. Because the moles of oxygen is calculated to be slightly less than 5 for all values of x and y, there must exist some value, z, of oxygen vacancies ( [symbol] ). After accounting for the oxygen vacancies, the resulting value of oxygen is 5-z.

U.S. Pat. No. 6,624,420 to Chai et al., yet another pioneering patent in the field, teaches co-doped scintillation crystals composed of cerium activated lutetium yttrium oxyorthosilicate (Ce:LYSO) having the formula Ce₂ₓ(Lu_{1-y}Y_{y})₂(1-x)SiO₅. In this solid-state composition, yttrium (Y) and cerium (Ce) each replace some of the lutetium (Lu):

$$( 1 - y - x - xy ) mol {Lu}_{2} {O}_{3} + x mol {CeO}_{2} + ( y - xy ) mol {Y}_{2} {O}_{3} + 1 mol {SiO}_{2} \to 1 mol {Ce}_{2 x} ( \text{?} {Y}_{y} \text{?} {SiO}_{5}$$

$$\text{?} \text{indicates text missing or illegible when filed}$$

The range of variables x and y are defined as 0.0001<x<0.05 and 0.0001<y<0.9999. Therefore, the entire range of each element's formula unit (f.u.) value claimed within the general composition of the '420 patent to Chai may be expressed as the following:

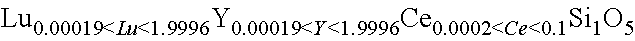

U.S. Pat. No. 7,132,060 to Zagumennyi et al., still yet another pioneering patent in the field, teaches various enhanced scintillation crystals composed of cerium-activated lutetium oxyorthosilicate having the formula CeₓLu_{2+2y-x-z}A_{z}Si_{1-y}O_{5+y}, but wherein at least one additional element denoted as “A” may substitute for other atoms within the overall crystal lattice structure. In addition, and unlike the exact 1:1 mole ratio of starting components taught for melts used to make prior art lutetium oxyorthosilicate crystals, the substituted co-doped Ce:LSO and/or Ce:LYSO scintillation crystals taught by the '060 patent are grown from non-stoichiometric melts wherein the silicon concentration is slightly less than one (Si<1) and the mole ratios of other components relative to silicon is slightly greater than two (i.e., Lu_{2+2y-x-z}+Ceₓ+A_{z})/Si>2).

Despite recent advancements in crystal growth techniques, there is still a need in the art for new and improved crystal growth methods and devices that can reliably produce high-quality advanced lutetium-based cerium-activated oxyorthosilicate scintillation crystals of uniform composition suitable for molecular imaging and/or high energy physics applications, as well as to the grown crystals themselves. The present invention fulfills this need and provides for further related advantages.

### BRIEF SUMMARY OF THE INVENTION

In accordance with certain embodiments of the present invention, a method is provided for growing a boule of co-doped LYSO:Ce, Ca scintillation crystal having enhanced scintillation performance and uniformity. The method involves providing an iridium crucible and loading it with a powdered mixture of specific oxides and a carbonate salt in specific relative amounts. A vacuum is applied to the loaded crucible, which is then pressurized with a specific gas mixture (i.e., mostly argon admixed with a small amount of carbon monoxide) to within a specified atmospheric pressure range (i.e., generally from about 1.02 to 1.05 atm). The loaded and pressurized crucible is then heated to yield a melt, into which a seed crystal is placed to grow an unfinished crystalline boule via the Czochrolaski pulling method. The unfinished boule is then annealed at a specific temperature range for a selected duration with the same specific gas mixture (i.e., mostly argon admixed with a small amount of carbon monoxide) at an elevated atmospheric pressure to yield a finished crystalline boule of co-doped LYSO:Ce,Ca.

In accordance with other embodiments, the method may include adjusting various parameters such as the relative amounts of the starting oxide materials and the carbonate salt, the specific pressure environment, and the heat treatment temperatures and durations. The method generally also involves using iridium crucibles that are in direct contact with one or more zirconia insulation materials. The crystalline boules grown in accordance with the invention preferably contain both Ce³⁺ ions and Ce⁴⁺ ions uniformly distributed throughout the boule in a ratio of about 1:1 (i.e., about 50% trivalent cerium Ce³⁺ ions to about 50% tetravalent cerium Ce⁴⁺ ions), but may, however, numerically range from about 40%-60% trivalent cerium Ce³⁺ ions to about 40%-60% tetravalent cerium Ce⁴⁺ ions.

In an embodiment, the invention is directed to a co-doped cerium and calcium lutetium-yttrium oxyorthosilicate scintillation crystal (substantially free of other ions) represented by the following chemical formula:

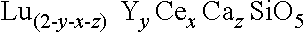

wherein
x is ≥0.0001 and ≤0.02
y is ≥ zero and ≤0.1
z is ≥0.0001 and ≤0.005
and wherein Ce³⁺ ions and Ce⁴⁺ ions are present within the crystal in a ratio of about 1:1. Put differently, the ratio of Ce³⁺ ions and Ce⁴⁺ ions within crystals grown in accordance with the present invention is preferably equal to about 50:50 or 1:1 (i.e., about 50% trivalent cerium Ce³⁺ ions to about 50% tetravalent cerium Ce⁴⁺ ions), but may numerically range from about 40%-60% trivalent cerium Ce³⁺ ions to about 40%-60% tetravalent cerium Ce⁴⁺ ions.

In another embodiment, boules of co-doped LYSO:Ce, Ca scintillation crystal are grown from slightly non-stoichiometric melts in which the silicon concentration is slightly less than one (Si<1) and the mole ratios of other components relative to silicon is greater than two (i.e., Lu_{2-y-x-z}+Y_{y}+Ceₓ+Ca_{z})/Si>2). Thus, the invention is also directed to a co-doped cerium and calcium lutetium-yttrium orthosilicate scintillation crystal (substantially free of other ions) represented by the following chemical formula:

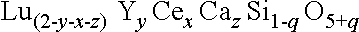

wherein
x is ≥0.0001 and ≤0.02
y is ≥ zero and ≤0.1
z is ≥0.0001 and ≤0.005
q is ≥ zero and ≤0.0001
and wherein Ce³⁺ ions and Ce⁴⁺ ions are present within the crystal in a ratio of about 1:1.

These and other aspects of the present invention will become more readily apparent to those of ordinary skill in the art when reference is made to the following detailed description in view of the accompanying drawings.

### BRIEF DESCRIPTION OF THE DRAWINGS

The drawings are intended to be illustrative of certain preferred embodiments of the present invention. Like reference numerals have been used to designate like steps or features throughout the several views of the drawings.

FIG. 1 illustrates, in a flowchart format, the steps associated with growing a co-doped LYSO:Ce, Ca crystal boule in accordance with certain embodiments of the present invention.

FIG. 2 illustrates a crystal growing device suitable for growing a co-doped LYSO:Ce, Ca crystal boule in accordance with the present invention.

FIG. 3 is a representative XANES spectrograph illustrating a cerium atom step edge of a co-doped LYSO:Ce, Ca crystal pixel grown accordance with an embodiment of the present invention.

### DETAILED DESCRIPTION OF THE INVENTION

In the following detailed description, reference is made to the accompanying drawings, which form a part hereof. In the drawings, similar symbols or markings have been used to identify like or corresponding steps or elements, unless context dictates otherwise. The illustrative embodiments described in the detailed description, drawings, and claims are not meant to be limiting and are not necessarily to scale. Other embodiments may be utilized, and other changes may be made, without departing from the scope of the invention as defined by the appended claims.

As is appreciated by those skilled in the art, lutetium-based oxyorthosilicate crystals, commonly represented by the generic chemical formula [Lu₍₁₋ₓ₎Yₓ]₂SiO₅:Ce or more simply as LYSO:Ce and even more simply as just LYSO, generally have a variable yttrium and cerium content depending on the grower/manufacturer and end user prefaces. Both of these co-dopants are related to fundamental properties of the crystals. The yttrium content generally correlates with the mass density (and consequently with the minimum ionizing particle (MIP) deposited energy), while the cerium content generally relates to light yield and decay time. In addition, the stoichiometry of the metal (Lu₍₁₋ₓ₎Yₓ) group is not entirely fixed and depends on the precise crystal growth recipe of each manufacturer (values for x, however, are generally less than 10% of the total metal content). The large difference between the atomic mass of lutetium (174.967 amu) and yttrium (88.906 amu) accounts for significant differences between the densities of lutetium-based oxyorthosilicate crystals having different yttrium content.

There are a number of qualities that make different crystals more or less useful as scintillators, including their light yield, their decay rate, their energy resolution, and their afterglow. In all cases, the physical properties of any substance (including crystals) are determined solely by its chemical composition and the arrangement of the chemical constituent components that make up its composition. The scintillation crystals of the present invention as disclosed herein strike a unique balance of these properties, whereas the methods of the present invention enable the growth of large crystalline boules of a uniform composition possessing these properties. In the context of the present invention, a scintillator's “light yield” is a measure of how bright it becomes when struck by ionizing radiation, a scintillator's “decay rate” describes how quickly the scintillator returns to its unlit state after lighting up, a scintillator's “energy resolution” is essentially a measure of the width of the light beam emitted by the scintillator when it lights up—that is, the energy resolution is the ratio (expressed as a percentage) of the light yield over the wavelength of the light at full width/half maximum (FWHM).

In next generation positron emission tomography (PET) medical scanners, for example, scintillation crystals with higher light yields, faster decay rates, narrower energy resolutions, and lower afterglows are preferred. The co-doped LYSO:Ce,Ca scintillation crystals grown in accordance with the present invention are particularly well-suited for use in PET scanners because of their unique mix of favorable physical properties. In the context of the present invention, a dopant refers to an element or compound that is intentionally added to the crystal lattice structure to modify its properties and/or enhance its sensitivity to certain types of radiation, such as gamma rays. A co-dopant refers to one or more additional elements or compounds that are introduced into the melt/crystal along with the original first dopant. Thus, a co-doped scintillation crystal refers to a scintillation crystal that has been doped with two or more additional elements or compounds.

The scintillation performance of lutetium-based oxyorthosilicate crystals also depends on several other additional factors. For example, and without necessarily prescribing to any specific scientific theory, it is believed that the intensity of the optical absorption peak at 360 nm directly correlates to the concentration of trivalent Ce³⁺ ions within the crystal, whereas the scintillation light output (LO) directly correlates the concentration of tetravalent Ce⁴⁺ ions within the crystal. In accord with the present invention, the ratio between these two ions is controlled, in large part, by precise co-doping of the crystal with precise amounts Ca²⁺ ions (introduced by adding small amounts of calcium carbonate (CaCO₃) as a starting ingredient, which compound favorably decomposes under heat to yield Ca²⁺ ions, O²⁻ ions, and gaseous CO as follows: CaCO₃→Ca²⁺+O²⁻+CO) while growing the crystal in the manner as herein described.

In some embodiments, the co-doped LYSO:Ce, Ca scintillation crystals of the present invention are substantially free of other metallic ions such as, for example, monovalent lithium ions Li⁺ and/or bivalent magnesium ions Mg²⁺ because more than de minimis amounts of these and other types of charged ions interfere with the scintillation process in undesirable and/or unwanted ways.

In accordance with the methods of the present invention, large boules of co-doped LYSO:Ce, Ca scintillation crystals may be grown such that the number trivalent Ce³⁺ ions and the number of tetravalent Ce⁴⁺ ions are about the same. Put differently, the ratio of Ce³⁺ ions and Ce⁴⁺ ions within crystals grown in accordance with the present invention is preferably equal to about 50:50 or about 1:1 (i.e., about 50% trivalent Ce³⁺ ions to about 50% tetravalent Ce⁴⁺ ions), but may numerically range from about 40%-60% trivalent Ce³⁺ ions to about 40%-60% tetravalent Ce⁴⁺ ions (depending on the specifics of the crystal growth recipe and growing/annealing conditions). In the context of the present invention, a large boule refers to any boule having a diameter of greater than 80 millimeters (mm) and a length of greater than 220 millimeters (mm). Again, and with necessarily prescribing to any specific scientific theory, it is believed that scintillation performance is optimized when LYSO:Ce, Ca scintillation crystals are grown such the ratio of Ce³⁺ ions and Ce⁴⁺ ions within crystals are roughly the same.

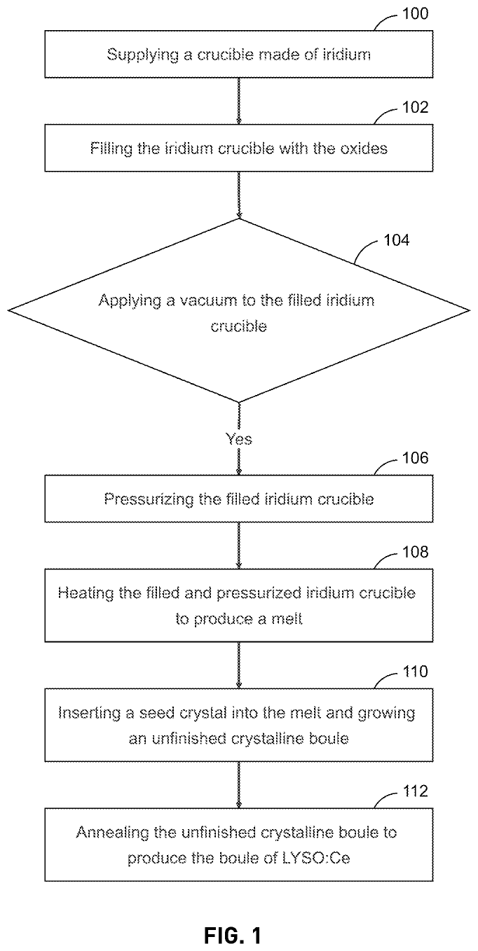

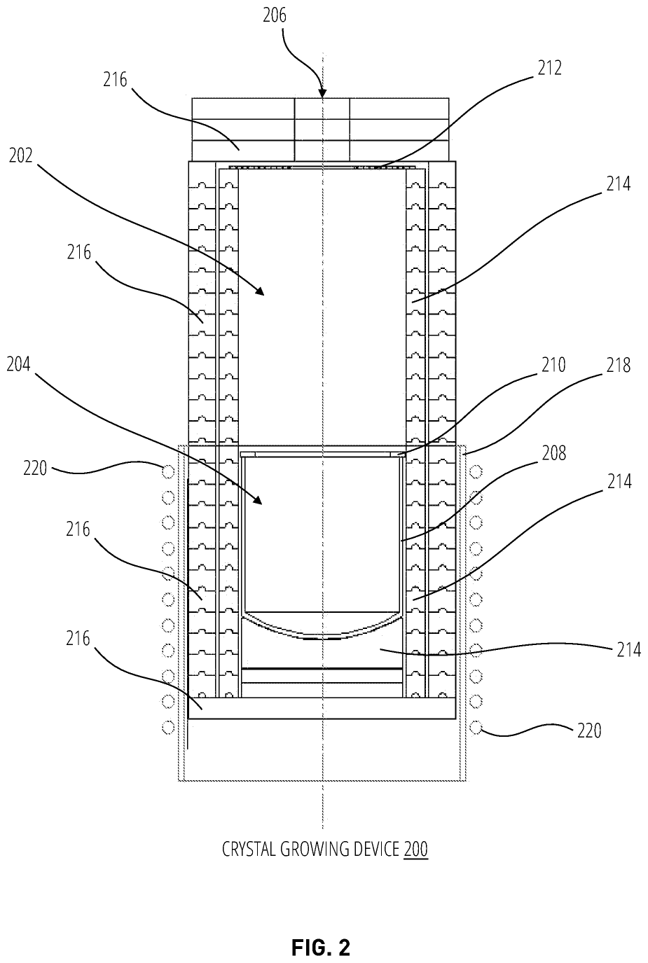

In view of the foregoing and referring now to the drawings, the present invention in an embodiment is directed to a method of growing a boule of co-doped LYSO:Ce,Ca scintillation crystal, wherein the ratio of Ce³⁺ ions and Ce⁴⁺ ions within the boule are roughly the same. The crystal growth method involves the several different process steps illustrated in FIG. 1. In addition, the process steps illustrated in FIG. 1 are preferably carried out using the specialized crystal growing device 200 shown in FIG. 2 (because this novel configuration creates a more uniform and stable thermal field, which thermal field facilitates crystal growth and enables the growth of large crystal boules of exceptional quality and uniformity).

More specifically, and with reference to FIG. 1 in view of FIG. 2, and starting with step 100, the novel crystal growing process of the present invention begins by supplying an iridium crucible 208. The iridium crucible 208, when filled with measured amounts of the starting compounds (i.e., lutetium oxide Lu₂O₃, yttrium oxide Y₂O₃, silicon dioxide SiO₂, cerium oxide CeO₂, as well as calcium carbonate CaCO₃) is used to melt or otherwise alter its contents. The iridium crucible 208 is used to hold the different starting solid oxides and the carbonate salt (generally in powdered form and 99.999% pure) that, as part of the process, are melted together to form the melt used to grow the boule (not shown). Here, and as shown in FIG. 2, the iridium crucible 208 is a part of (i.e., an inner component of) a larger crystal growing device 200. The iridium crucible 208 can withstand temperatures on the order of 2100 degrees Celsius.

As shown in FIG. 2, the crystal growing device 200 of the present invention comprises an upper portion 202 and a lower portion 204. As shown, a generally doughnut-shaped iridium lid 210 is fitted on top of the iridium crucible 208 and separates the upper portion 202 from the lower portion 204. An iridium semi-ring 212 is similarly fitted near the top of the upper portion 202 and communicates with an opening 206 (used to add ingredients and for insertion of a seed crystal positioned at the end of a rod—not shown). As shown, the iridium crucible 208 is surrounded by two distinct types of thermal insulation; namely, a deoxidized zirconia insulation material 214 and a zirconia insulation material 216. The deoxidized zirconia insulation material 214 surrounds, and is in direct contact with, the iridium crucible 208, whereas the zirconia insulation material 216 surrounds, and is in direct contact with, the deoxidized zirconia insulation material 214. It has been found, surprisingly, that using two different types of zirconia-based insulation material better protects the iridium crucible 208 from loss of iridium over extended use (thereby reducing costs).

In addition, and as further shown, a housing 218, positioned about the lower portion 204 of the crystal growing device 200, surrounds and holds in place the iridium crucible 208 and a portion of the two types of insulation (deoxidized zirconia insulation material 214 and zirconia insulation material 216). An induction coil 220 (water cooled) wraps around the housing 218 and is used to inductively and selectively/controllably heat the iridium crucible 208 and it contents.

By growing crystals in a crystal growing device 200 comprising concentric insulation of two different types as described herein, it has been found that iridium losses minimized while the thermal field, created as part of the heating, melting, and annealing process steps, is exceptionally uniform and stable (thereby by allowing the growth of superior crystals-including large crystal boules of co-doped LYSO:Ce, Ca having uniform composition and favorable scintillation dynamics).

With reference again to FIG. 1, and in step 102, the iridium crucible 208 is initially filled with specific chemical compounds in specific amounts. Here, and in the practice of the invention, the following oxides/carbonate salt and relative amounts (given in ranges) on a weight percent basis are used: Lu₂O₃ at about 85 to 86 parts, Y₂O₃ at about 1 to 2 parts, SiO₂ at about 13 to 13.5 parts, CaCO₃ at about 0.02 parts, and CeO₂ at about 0.09 parts. These starting compounds, in precisely measured amounts, are placed into the iridium crucible 208 in this step.

Step 104 involves applying a vacuum to the filled iridium crucible 208. This may be done using a vacuum pump, for example. The purpose of this step is to remove any air or other gases from the iridium crucible 208, creating a low pressure environment. This is important because it helps to prevent unwanted reactions between the chemical compounds and the gases in the air.

In step 106, the filled iridium crucible 208 is pressurized with a mixture of gases consisting essentially of about 95% to about 99.9% Ar and, more preferably, from about 0.1% to about 5% CO on a weight percent basis, and more even preferably from about 99.75% Ar to about 0.25% CO on a weight percent basis. The pressure is maintained from about 1.02 to 1.05 atm (during the crystal growth and annealing steps). This step is important because it helps to ensure that the crystal attains a uniform composition and favorable scintillation dynamics.

Step 108 involves heating the pressurized iridium crucible 208 to produce a melt. This is generally done using inductive heating (and within the specialized crystal growing device 200). The temperature is carefully controlled to ensure that the chemical compounds melt but do not otherwise degrade. The result is a molten material that is ready for the next step.

In step 110, a seed crystal secured at the end of a rod is inserted into the melt via the opening 206. The seed crystal provides a template for the molten material to crystallize around, helping to form into a crystalline boule (in accordance with the Czochrolaski melt pulling method as is known in the art). More particularly, as the crystal forms around the seed crystal, the rod is slowly withdrawn from the melted material, a process that results in a cylindrical crystal known as a boule.

Finally, in step 112, the unfinished crystalline boule is annealed. This step is also generally done within the specialized crystal growing device 200. The annealing temperature preferably is constant and ranges from about 1450° C. to about 1500° C. The heat-up time is about 24 hours, the constant temperature time is about 48 hours, and the cool-down time is about 48 hours. Annealing in this way helps to relieve any internal stresses in the boule, improving its structural integrity and optical properties. The result is a finished boule of co-doped LYSO:Ce, Ca scintillation crystal. In addition, and after finishing its growth, the boule may be cut into many smaller crystals referred to as pixels, which, for example, can then be installed into the detector ring of a PET scanner. Such pixels can be tailored, depending on the application, to have a decay time of between 30 to 40 nanoseconds (ns).

Stated somewhat differently, the process of the invention begins by providing a crucible made of iridium. The iridium crucible 208 is then filled with the following compounds and relative amounts on a weight percent basis: Lu₂O₃ at about 85 to 86 parts, Y₂O₃ at about 1 to 2 parts, SiO₂ at about 13 to 13.5 parts, CaCO₃ at about 0.02 parts, and CeO₂ at about 0.09 parts. Once the crucible is filled, a vacuum of about 0.1 Pa is applied to the filled iridium crucible 208. The filled iridium crucible is then pressurized with an atmosphere consisting essentially of about 99.75% Ar and 0.25% CO on a weight percent basis, and to an atmospheric pressure ranging from about 1.02 to 1.05 atm. The filled and pressurized iridium crucible 208 is then heated to produce a molten mixture. A seed crystal is then inserted into the molten liquid mixture to initiate the growth of the boule. Next, the unfinished boule is then annealed at a temperature ranging from about 1450° C. to 1500° C. for a selected period of time (e.g., 48 hours) with an atmosphere consisting essentially of about 99.75% Ar and 0.25% CO on a weight percent basis at an atmospheric pressure ranging from about 1.02 to 1.05 atm. The end product of this process, is a single crystal of LYSO:Ce, Ca having a ratio of Ce³⁺ ions to Ce⁴⁺ within the crystal of about 1:1. This particular LYSO:Ce, Ca formulation can be advantageously used in various applications, including as a scintillator in molecular imaging devices and in high energy physics.

For purposes of illustration and not limitation, the following examples more specifically disclose the different amounts (representative weights in grams) of the starting compounds (i.e., essentially pure Lu₂O₃, Y₂O₃, SiO₂, CaCO₃, and CeO₂) that were used to successfully grow successive (batch-wise) crystalline boules of co-doped LYSO:Ce,Ca in accordance with the methods and devices of the present invention.

### EXAMPLES

| Required weight of | | Required weight of | | Required weight of | |
|---|---|---|---|---|---|
| the oxides (dry result): | | the oxides (wet result): | | the oxides (final result): | |
| Lu₂O₃ | 6883.61200 | Lu₂O₃ | 6906.19500 | Lu₂O₃ | 6906.19500 |
| Y₂O₃ | 99.79998 | Y₂O₃ | 100.4832 | Y₂O₃ | 100.4832 |
| SiO₂ | 1056.89180 | SiO₂ | 1057.00000 | SiO₂ | 1057.00000 |
| CaCO₃ | 1.76942 | CaCO₃ | 1.76942 | CaCO₃ | 1.36084 |
| CeO₂ | 6.0853 | CeO₂ | 6.0853 | CeO₂ | 6.0853 |
| Total | 8048.15850 | Total | 8071.53292 | Total | 8071.12434 |
| Lu₂O₃ | 4623.17330 | Lu₂O₃ | 4638.34000 | Lu₂O₃ | 4638.34000 |
| Y₂O₃ | 50.1461 | Y₂O₃ | 50.4894 | Y₂O₃ | 50.4894 |
| SiO₂ | 709.92360 | SiO₂ | 709.92360 | SiO₂ | 710.92360 |
| CaCO₃ | 0.47220 | CaCO₃ | 0.47220 | CaCO₃ | 0.20670 |
| CeO₂ | 1.3898 | CeO₂ | 1.3898 | CeO₂ | 1.3898 |
| Total | 5385.10500 | Total | 5400.61500 | Total | 5401.34950 |
| Lu₂O₃ | 42.76930 | Lu₂O₃ | 42.76930 | Lu₂O₃ | 85.53860 |
| Y₂O₃ | 0.4638 | Y₂O₃ | 0.62 | Y₂O₃ | 1.24 |
| SiO₂ | 6.56670 | SiO₂ | 6.56670 | SiO₂ | 13.13340 |
| CaCO₃ | 0.00000 | CaCO₃ | 0.00000 | CaCO₃ | 0.02200 |
| CeO₂ | 0.0000 | CeO₂ | 0.0000 | CeO₂ | 0.0929 |
| Total | 49.79980 | Total | 49.95600 | Total | 100.02690 |

Representative weights (in grams) of the starting oxides added to crucible for different grows.

In the practice of the invention and with reference to the above starting compounds and their respective weight amounts, large boules of co-doped LYSO:Ce, Ca scintillation crystal were grown inaccordance with the following steps: load starting oxides into iridium crucible; vacuum to about 0.1 Pa; introduce Argon (containing about 0.25% CO) to about 1.02-1.05 atmospheres; heat up for about 12 hours to melt starting oxides; find the right melt temperature (about 4 hours); insert seed crystal into the melt and begin pull (about 4 hours); crystal shoulder expansion pull (about 24 hours); crystal equal diameter pull (about 124 hours); crystal tail pull (about 4 hours); crystal annealing (about 48 hours); remove the finished crystal.

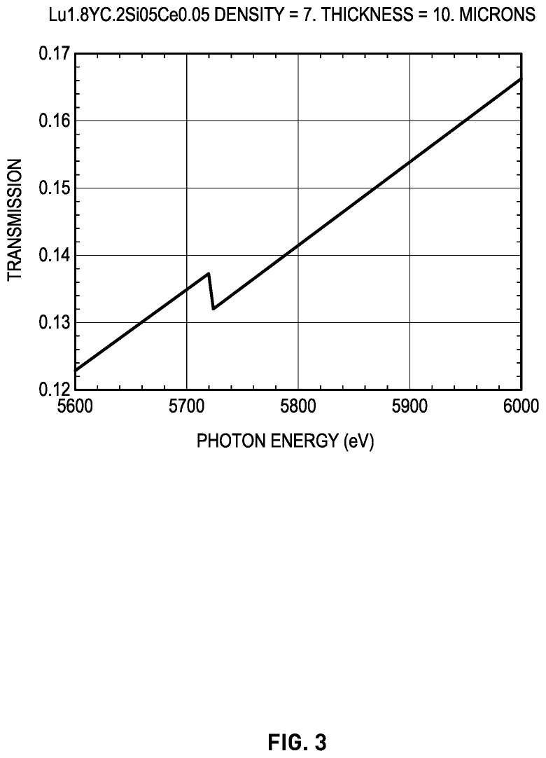

With respect to detection and quantification of the amount of Ce³⁺ ions and Ce⁴⁺ ions present within an individual LYSO crystal, it has been determined that X-ray Absorption Near Edge Structure (XANES) is presently the most appropriate testing methodology. XANES is a spectroscopic technique used to study the electronic structure and local chemical environment of atoms within a material. It focuses on the X-ray absorption near the ionization energy of core electrons, providing detailed information about the oxidation state and coordination environment of the absorbing atom. XANES can distinguish between different oxidation states of an element like cerium (i.e., Ce³⁺ ions and Ce⁴⁺ ions) because the absorption edge position shifts depending on the oxidation state. XANES measurements typically require synchrotron radiation due to the need for highly intense and tunable X-rays. A representative spectrograph (of a co-doped LYSO:Ce,Ca crystal pixel) is provided as FIG. 3 illustrating a small signal edge (edge step) at a photon energy of about 5720 eV.

While the present invention has been described in the context of the embodiments illustrated and described herein, the invention may be embodied in other specific ways or in other specific forms without departing from its scope or essential characteristics. Therefore, the described embodiments are to be considered in all respects as illustrative and not restrictive. The scope of the invention is, therefore, indicated by the appended claims rather than by the foregoing descriptions, and all changes that come within the meaning and range of equivalency of the claims are to be embraced within their scope.

What is claimed is:

1. A cerium and calcium lutetium-yttrium oxyorthosilicate scintillation crystal represented by the following chemical formula: 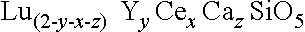
wherein
x is ≥0.0001 and ≤0.02
y is ≥ zero and ≤0.1
z is ≥0.0001 and ≤0.005
and wherein Ce³⁺ ions and Ce⁴⁺ ions are present within the crystal in a ratio of about 40%-60% Ce³⁺ ions to about 40%-60% Ce⁴⁺ ions.

2. The cerium and calcium lutetium-yttrium oxyorthosilicate scintillation crystal of claim 1 wherein the Ce³⁺ ions and Ce⁴⁺ ions are present within the crystal in a ratio of about 50% Ce³⁺ ions to about 50% Ce⁴⁺ ions.

3. A co-doped cerium and calcium lutetium-yttrium oxyorthosilicate scintillation crystal represented by the following chemical formula: 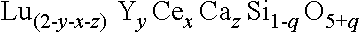
wherein
x is ≥0.0001 and ≤0.02
y is ≥ zero and ≤0.1
z is ≥0.0001 and ≤0.005
q is ≥ zero and ≤0.0001
and wherein Ce³⁺ ions and Ce⁴⁺ ions are present within the crystal in a ratio of about 40%-60% trivalent Ce³⁺ ions to about 40%-60% tetravalent Ce⁴⁺ ions.

4. The co-doped cerium and calcium lutetium-yttrium oxyorthosilicate scintillation of claim 3 wherein the Ce³⁺ ions and Ce⁴⁺ ions are present within the crystal in a ratio of about 50% Ce³⁺ ions to about 50% Ce⁴⁺ ions.

5. A lutetium-yttrium oxyorthosilicate scintillation crystal co-doped with calcium and cerium, wherein the crystal comprises Ce³⁺ ions and Ce⁴⁺ ions in a ratio of about 40-60% Ce³⁺ ions to about 40-60% Ce⁴⁺ ions.

6. The lutetium-yttrium oxyorthosilicate scintillation crystal co-doped with calcium and cerium of claim 5 wherein the crystal comprises Ce³⁺ and Ce⁴⁺ ions in a ratio of about 50% Ce³⁺ ions to about 50% Ce⁴⁺ ions.
